(19) United States
(12) Patent Application Publication
(10) Pub. No.: US 2025/0076601 A1
(43) Pub. Date: Mar. 6, 2025

(54) OPTICAL RECEIVING MODULE ASSEMBLY

(71) Applicant: Electronics and Telecommunications Research Institute, Daejeon (KR)

(72) Inventors: Won-Bae KWON, Daejeon (KR); Eun Kyu KANG, Daejeon (KR); Jong Jin LEE, Daejeon (KR); Soo Yong JUNG, Daejeon (KR); Haechung KANG, Daejeon (KR); Myunghwan KIM, Daejeon (KR); Dae Woong MOON, Daejeon (KR); Gye Sul CHO, Daejeon (KR)

(73) Assignee: Electronics and Telecommunications Research Institute, Daejeon (KR)

(21) Appl. No.: 18/765,891

(22) Filed: Jul. 8, 2024

(30) Foreign Application Priority Data
Aug. 29, 2023 (KR) 10-2023-0113454
Sep. 20, 2023 (KR) 10-2023-0125334

(51) Int. Cl. G02B 6/43; G02B 6/42; H04B 10/40; H05K 1/02

(52) U.S. Cl. CPC G02B 6/43; G02B 6/4238; G02B 6/4246; G02B 6/428; H04B 10/40; H05K 1/0274; H05K 2201/0108

(57) ABSTRACT

An optical receiving module assembly is provided. The optical receiving module assembly includes an electric sub-assembly including a printed circuit board (PCB) including an opening portion and an electronic device mounted on the PCB and an optical receiving module including a first optical component mounted on the PCB and a second optical component mounted on the mount which includes a transparent material and is disposed in the opening portion, wherein the electronic device and the second optical component are electrically connected to each other by a mount electrode formed on a surface of the mount.

### CROSS-REFERENCE TO RELATED APPLICATIONS

This application claims the benefit of the Korean Patent Application Nos. 10-2023-0113454 filed on Aug. 29, 2023, and 10-2023-0125334 filed on Sep. 20, 2023, which are hereby incorporated by reference as if fully set forth herein.

### BACKGROUND

### Field of the Invention

The present invention relates to an optical receiving module assembly, and more particularly, to an optical receiving module assembly for minimizing radio frequency (RF) transmission loss.

### Discussion of the Related Art

FIG. 1 is a diagram for describing a quad small form factor pluggable (QSFP) or octal small form factor pluggable (OSFP) optical module assembly of the related art.

Referring to FIG. 1, the optical module assembly of the related art includes a transmitter optical sub-assembly (TOSA) 10 which converts an electric signal into an optical signal, a receiver optical sub-assembly (ROSA) 20 which converts an input optical signal into an electric signal, an electric sub-assembly (ESA) 30 which includes a printed circuit board (PCB) 32 and an electronic device 34 mounted on the PCB 32, and a flexible PCB (FPCB) 60 which electrically connects the TOSA 10 and the ROSA 20 to the ESA 30.

The FPCB 60 may secure easiness in a bonding process between the FPCB 60 and the ESA 30, based on a flexible material characteristic. However, because a thickness of the FPCB 60 should be designed to be thin for securing flexibility, there is technical difficulty in that a line width of a transmission line should be reduced and a manufacturing process error of a line width should be minimized, for the accuracy and impedance matching of a high frequency transmission line.

Moreover, the FPCB 60 should be designed to have a certain length Lfpcb, for securing flexibility, and due to this, high frequency transmission loss increases, an electric bandwidth is reduced, and a miniaturization design of the optical module assembly is difficult.

Moreover, because the FPCB 60 includes an opaque material, it is difficult to discern a position for aligning an electrode of the PCB 32 and an electrode of the FPCB 60. Due to this, an alignment error between two electrodes in a bonding process between the FPCB 60 and the ESA 30 occurs. Due to such an alignment error, impedance mismatching may occur in an electrode bonding part 62.

Moreover, in order to connect the electrode of the FPCB 60 to optical devices included in the TOSA 10 and the ROSA 20, a package feedthrough 70 is designed on an outer wall of each of the TOSA 10 and the ROSA 20 generally, and due to this, the total price of an optical module increases.

### SUMMARY

An aspect of the present invention is directed to providing an optical receiving module assembly in which an optical component (for example, a photodetector) of an optical receiving module (10 or 20 of FIG. 1) is mounted on a mount including a transparent material and an electrode of an electronic device in the electric sub-assembly is connected to an electrode of the optical component through a mount electrode formed in the mount including the transparent material, and thus, the electronic device of the electric sub-assembly is connected to the optical component of the optical receiving module by a shortest distance, thereby minimizing a transmission line length to enhance an electrical bandwidth.

Moreover, the present invention provides an optical receiving module assembly in which the FPCB (60 of FIG. 1) and the package feedthrough (70 of FIG. 1) of the related art are replaced with a glass mount including the transparent material, thereby accomplishing product miniaturization and a reduction in manufacturing cost.

To achieve these and other advantages and in accordance with the purpose of the invention, as embodied and broadly described herein, there is provided an optical receiving module assembly including: an electric sub-assembly including a printed circuit board (PCB) including an opening portion and an electronic device mounted on the PCB; and an optical receiving module including a first optical component mounted on the PCB and a second optical component mounted on the mount which includes a transparent material and is disposed in the opening portion, wherein the electronic device and the second optical component are electrically connected to each other by a mount electrode formed on a surface of the mount.

In an embodiment, a portion of the electronic device may be disposed on the mount, and an electrode formed at a portion of the electronic device may be bonded to the mount electrode by a local laser soldering process.

In an embodiment, an electrode formed in the electronic device and the mount electrode may be aligned by the mount including the transparent material with eyes.

In an embodiment, an electrode formed in the electronic device and the mount electrode may be bonded to each other by a solder bump which is cooled after being melted by a high power laser passing through the mount including the transparent material.

In an embodiment, the mount including the transparent material may include a glass or plastic material.

In an embodiment, the mount may be fixed by an adhesive coated on a side surface of the PCB including the opening portion with being disposed at the opening portion.

In an embodiment, the adhesive may include an epoxy-based adhesive.

In an embodiment, the second optical component may convert light, which is vertically incident from the first optical component, into an electrical signal to output to the electronic device through the mount electrode.

In an embodiment, the first optical component may be an optical waveguide including an optical slope surface for allowing the light to be vertically incident on the photodetector.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a diagram for describing a quad small form factor pluggable (QSFP) or octal small form factor pluggable (OSFP) optical module assembly of the related art.

FIG. 2 is a schematic side view of an optical receiving module assembly according to an embodiment of the present invention.

FIG. 3 is a plan view as the optical receiving module assembly of FIG. 2 is seen from above.

FIG. 4 is a diagram for describing a bonding process between a photodetector and an electronic device of FIG. 2.

### DETAILED DESCRIPTION OF THE INVENTION

Hereinafter, embodiments of the invention will be described in detail with reference to the accompanying drawings. In describing the invention, to facilitate the entire understanding of the invention, like numbers refer to like elements throughout the description of the figures, and a repetitive description on the same element is not provided.

In the following description, the technical terms are used only for explain a specific exemplary embodiment while not limiting the present invention. The terms of a singular form may include plural forms unless referred to the contrary. The meaning of ‘comprise’, ‘include’, or ‘have’ specifies a property, a region, a fixed number, a step, a process, an element and/or a component but does not exclude other properties, regions, fixed numbers, steps, processes, elements and/or components.

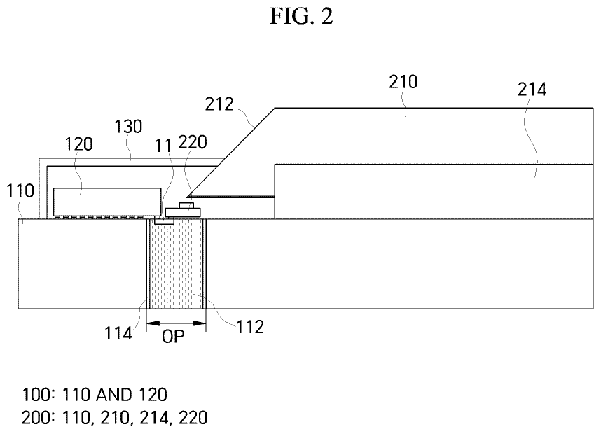

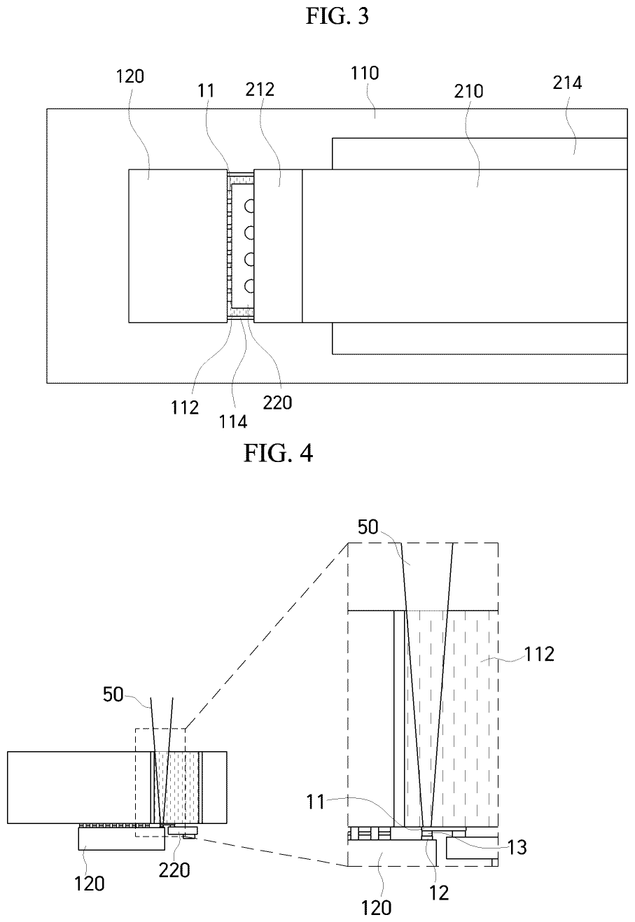

FIG. 2 is a schematic side view of an optical receiving module assembly according to an embodiment of the present invention, and FIG. 3 is a plan view as the optical receiving module assembly of FIG. 2 is seen from above and is a plan view of the optical receiving module assembly in a state where a cover of FIG. 2 is removed.

Referring to FIGS. 2 and 3, the optical receiving module assembly according to an embodiment of the present invention may include an electric sub-assembly 100 and an optical receiving module 200.

The electric sub-assembly 100 may include a printed circuit board (PCB) 110 including an opening portion OP and an electronic device 120 mounted on the PCB 110.

The electronic device 120 may include a pre-amplifier which amplifies an electrical signal transferred from an optical component 220 of the optical receiving module 200 through a mount electrode 11 formed in a mount 112 described below or/and a digital signal processor (DSP) which processes a signal.

The optical receiving module 200 may include a first optical component 210 mounted on the PCB 110, and a second optical component 220 mounted on the mount 112 which includes a transparent material and is disposed (or inserted) in the opening portion OP.

The electric sub-assembly 100 and the optical receiving module 200 may share the PCB 110. This may denote a structure where the optical receiving module 200 is embedded in the electric sub-assembly 100.

The first optical component 210 may be, for example, an optical waveguide device which is mounted on the PCB 110 by an optical waveguide mount 214. Unless described herein, reference numeral 210 may refer to the first optical component or the optical waveguide device. The second optical component 220 mounted on the mount 112 may be a photodetector. Unless described herein, reference numeral 220 may refer to the second optical component or the photodetector.

The optical waveguide device may include an optical slope surface 212 for allowing an input multi-wavelength optical signal to be vertically incident on the photodetector, which is the second optical component 220, through wavelength division de-multiplexing. The optical slope surface 212 may be, for example, a surface inclined by about 42 degrees to minimize back reflection as an optical signal is vertically incident on the photodetector. The photodetector may convert the optical signal, which is vertically incident from the optical waveguide device through the optical slope surface 212, into an electrical signal.

In order to minimize transmission loss, an impedance-matched mount electrode 11 may be formed (patterned) on a surface of the mount 112 which is disposed (or inserted) in the opening portion OP and includes the transparent material, and the high-speed electrical signal obtained through conversion by the photodetector 220 may be transferred to the electronic device 120 by the mount electrode 11.

To this end, a portion of the electronic device 120 may be disposed on the mount 112 including the transparent material, and an electrode (12 of FIG. 4) formed at a portion of the electronic device 120 and the mount electrode 11 formed (patterned) on the surface of the mount 112 including the transparent material may be bonded and electrically connected to each other by a local laser soldering process which will be described below with reference to FIG. 4.

As described above, the electronic device 120 and the photodetector 220 may be electrically connected to each other by the mount electrode 11 formed (patterned) on the surface of the mount 112 including the transparent material, without a conventional flexible circuit board, thereby minimizing the radio frequency (RF) transmission loss of an electrical signal.

The mount electrode 11 and the electrode (12 of FIG. 4) of the electronic device 120 may be bonded to each other by the local laser soldering process, and then, the mount 112 including the transparent material may be fixed and disposed by an adhesive 114 coated on a side surface of the PCB 110 including the opening portion OP with being inserted into the opening portion OP. Here, the adhesive 114 may use, for example, an epoxy-based adhesive.

Glass or plastic may be used as the mount 112 including the transparent material. Because the mount 112 includes the transparent material, positions of the electrodes 11 and 12 may be easily aligned with eyes before the mount electrode 11 formed in the mount 112 is bonded to the electrode (12 of FIG. 4) formed in the electronic device 120.

Furthermore, a cover (130 of FIG. 2) for protecting the electronic device 120 and the photodetector (which is the second optical component 220) from external dust and water may be disposed on the PCB 110. The cover 130 may include a sidewall which extends vertically from the PCB 110 and an upper surface which covers the electronic device 120, the photodetector which is the second optical component 220, and a portion of the optical slope surface 212 of the optical waveguide which is the first optical component 210.

FIG. 4 is a diagram for describing a bonding process between a photodetector and an electronic device of FIG. 2.

Referring to FIG. 4, because the mount 112 includes the transparent material, position alignment between the mount electrode 11 of the mount 112 and the electrode 12 of the electronic device may be easily performed with eyes.

After position alignment between the mount electrode 11 of the mount 112 and the electrode 12 of the electronic device is performed, bonding between the mount electrode 11 of the mount 112 and the electrode 12 of the electronic device may be easily performed through a local laser soldering process based on a high power laser 50.

That is, the mount electrode 11 of the mount 112 and the electrode 12 of the electronic device may be bonded to each other by a solder bump 13 which is cooled after being melted by the high power laser 50 passing through the mount 112 including the transparent material.

In the local laser soldering process, unlike a general soldering process, because the high power laser 50 is locally irradiated onto only the solder bump 13, a bonding process time may decrease, and a thermal stress may be minimized.

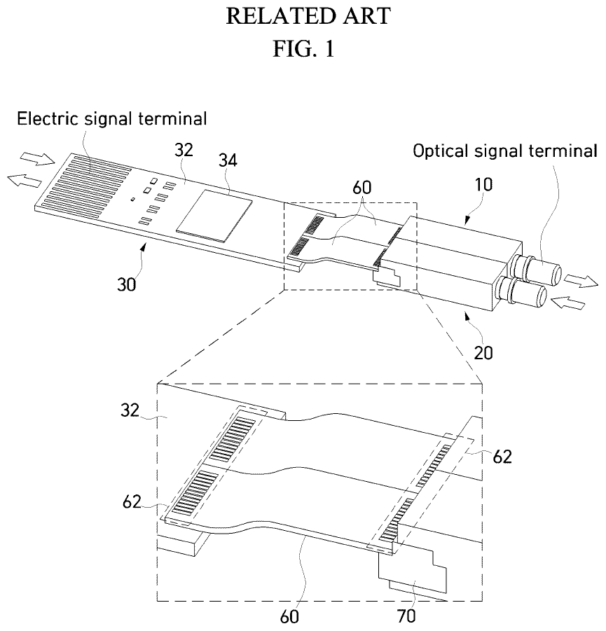

According to the embodiments of the present invention, the designs of the FPCB (60 of FIG. 1) and the package feedthrough (70 of FIG. 1) of the related art may be excluded, and a mount including a transparent material may be introduced to connect the electronic device of the electric sub-assembly to the optical component of the optical receiving module by a shortest distance, so as to minimize a transmission line length between the electronic device of the electric sub-assembly and the optical component (for example, a photodetector) of the optical receiving module, thereby enhancing an electrical bandwidth and accomplishing the miniaturization of an optical receiving module assembly.

Moreover, the electrode of the electronic device of the electric sub-assembly may be bonded (local laser soldering) to the electrode of the optical component of the optical receiving module by using a high power laser passing through the mount including the transparent material, and thus, a total process time of the optical receiving module assembly and the manufacturing cost may decrease.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An optical receiving module assembly comprising:
an electric sub-assembly including a printed circuit board (PCB) including an opening portion and an electronic device mounted on the PCB; and
an optical receiving module including a first optical component mounted on the PCB and a second optical component mounted on the mount which includes a transparent material and is disposed in the opening portion,
wherein the electronic device and the second optical component are electrically connected to each other by a mount electrode formed on a surface of the mount.

2. The optical receiving module assembly of claim 1, wherein a portion of the electronic device is disposed on the mount, and
an electrode formed at a portion of the electronic device is bonded to the mount electrode by a local laser soldering process.

3. The optical receiving module assembly of claim 1, wherein an electrode formed in the electronic device and the mount electrode are aligned by the mount including the transparent material with eyes.

4. The optical receiving module assembly of claim 1, wherein an electrode formed in the electronic device and the mount electrode are bonded to each other by a solder bump which is cooled after being melted by a high power laser passing through the mount including the transparent material.

5. The optical receiving module assembly of claim 1, wherein the mount including the transparent material comprises a glass or plastic material.

6. The optical receiving module assembly of claim 1, wherein the mount is fixed by an adhesive coated on a side surface of the PCB including the opening portion with being disposed at the opening portion.

7. The optical receiving module assembly of claim 6, wherein the adhesive comprises an epoxy-based adhesive.

8. The optical receiving module assembly of claim 1, wherein the second optical component converts light, which is vertically incident from the first optical component, into an electrical signal to output to the electronic device through the mount electrode.

9. The optical receiving module assembly of claim 8, wherein the first optical component is an optical waveguide including an optical slope surface for allowing the light to be vertically incident on the photodetector.
